(19) United States
(12) Patent Application Publication
(10) Pub. No.: US 2025/0253215 A1
(43) Pub. Date: Aug. 7, 2025

(54) SEMICONDUCTOR DEVICE, METHOD FOR MANUFACTURING SEMICONDUCTOR DEVICE, AND SUBSTRATE

(71) Applicant: KABUSHIKI KAISHA TOSHIBA, Tokyo (JP)

(72) Inventors: Toshihide TAKAHASHI, Yokohama (JP); Haruhiko MIYAGAWA, Odawara (JP); Kazuo SHIMOKAWA, Yokohama (JP)

(21) Appl. No.: 19/021,005

(22) Filed: Jan. 14, 2025

(30) Foreign Application Priority Data
Feb. 1, 2024 (JP) 2024-014275

(51) Int. Cl. H01L 23/495; H01L 23/00; H01L 23/31

(52) U.S. Cl. CPC H01L 23/49582; H01L 23/3121; H01L 23/49534; H01L 24/32; H01L 24/83; H01L 24/33; H01L 2224/32059; H01L 2224/32245; H01L 2224/33181; H01L 2224/83935

(57) ABSTRACT

A semiconductor device includes a lead frame, a first solder layer, a semiconductor element, and a sealing resin layer. The first solder layer is located on the lead frame. The lead frame includes a first base part, a first barrier metal layer, and a first adhesion layer. The first barrier metal layer is located on the first base part. The first barrier metal layer includes a first solder region and a first sealing region. The first barrier metal layer includes a metal having a diffusion rate into solder that is less than the diffusion rate into solder of copper. The first adhesion layer is located on the first sealing region. The first adhesion layer includes copper. The first solder layer is located on the first solder region. The sealing resin layer is located on the semiconductor element and on the first adhesion layer.

### CROSS-REFERENCE TO RELATED APPLICATIONS

This application is based upon and claims the benefit of priority from Japanese Patent Application No. 2024-014275, filed on Feb. 1, 2024; the entire contents of which are incorporated herein by reference.

### FIELD

Embodiments described herein relate generally to a semiconductor device, a method for manufacturing a semiconductor device, and a substrate.

### BACKGROUND

In a known semiconductor device, a semiconductor element is bonded to a lead frame via a solder layer; and the semiconductor element is sealed in a sealing resin. To guarantee the high-temperature operation of such a semiconductor device, it is desirable to realize both high-temperature reliability of the solder bonding portion and adhesion between the lead frame and the sealing resin. For example, in an automotive semiconductor device, it is desirable to realize both high-temperature reliability of the solder bonding portion and adhesion between the lead frame and the sealing resin at the high-temperature condition of 175° C.

### BRIEF DESCRIPTION OF THE DRAWINGS

FIG. 1 is a plan view illustrating a semiconductor device according to a first embodiment;

FIG. 2 is a cross-sectional view illustrating the semiconductor device according to the first embodiment;

FIG. 3 is a plan view illustrating a semiconductor device according to a second embodiment;

FIG. 4 is a cross-sectional view illustrating the semiconductor device according to the second embodiment;

FIG. 5 is a plan view illustrating a semiconductor device according to a third embodiment;

FIG. 6 is a cross-sectional view illustrating the semiconductor device according to the third embodiment;

FIG. 7 is a plan view illustrating a semiconductor device according to a fourth embodiment;

FIG. 8 is a cross-sectional view illustrating the semiconductor device according to the fourth embodiment;

FIG. 9 is a plan view illustrating a semiconductor device according to a fifth embodiment;

FIG. 10 is a cross-sectional view illustrating the semiconductor device according to the fifth embodiment;

FIG. 11 is a plan view illustrating a substrate according to an embodiment;

FIG. 12 is a cross-sectional view illustrating the substrate according to the embodiment;

FIGS. 13A to 13C are cross-sectional views illustrating portions of substrates according to the embodiment;

FIGS. 14A to 14D are cross-sectional views illustrating a method for manufacturing the semiconductor device according to the embodiment;

FIG. 15 is a graph illustrating an example of a reflow profile of the method for manufacturing the semiconductor device according to the embodiment;

FIG. 16 is a plan view illustrating the method for manufacturing the semiconductor device according to the embodiment;

FIG. 17 is a table illustrating results of examples and comparative examples;

FIGS. 18A and 18B are explanatory drawings illustrating a method for measuring the adhesion strength of the examples and the comparative examples;

FIG. 19 is a table illustrating results of the examples and the comparative examples; and

FIG. 20 is a table illustrating results of the examples and the comparative examples.

### DETAILED DESCRIPTION

A semiconductor device according to an embodiment includes a lead frame, a first solder layer, a semiconductor element, and a sealing resin layer. The first solder layer is located on the lead frame. The semiconductor element is located on the first solder layer. The sealing resin layer is located on the semiconductor element and on the lead frame. The lead frame includes a first base part, a first barrier metal layer, and a first adhesion layer. The first barrier metal layer is located on the first base part. The first barrier metal layer includes a first solder region and a first sealing region. The first barrier metal layer includes a metal having a diffusion rate into solder that is less than the diffusion rate into solder of copper. The first adhesion layer is located on the first sealing region. The first adhesion layer includes copper. The first solder layer is located on the first solder region. The sealing resin layer is located on the semiconductor element and on the first adhesion layer.

Embodiments of the invention will now be described with reference to the drawings.

The drawings are schematic or conceptual; and the relationships between the thickness and width of portions, the proportions of sizes among portions, etc., are not necessarily the same as the actual values. The dimensions and proportions may be illustrated differently among drawings, even when the same portion is illustrated.

In the specification and drawings, components similar to those described previously or illustrated in an antecedent drawing are marked with the same reference numerals; and a detailed description is omitted as appropriate.

### Semiconductor Device

### First Embodiment

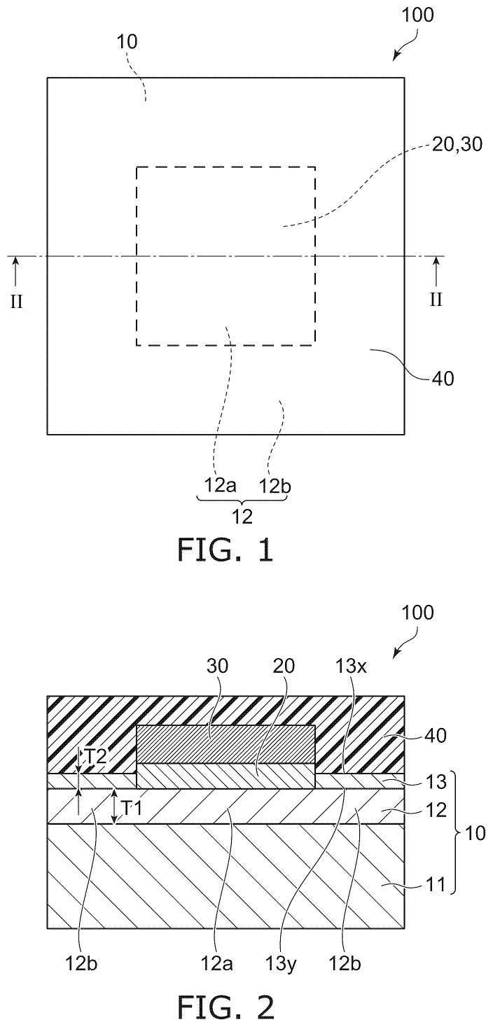

FIG. 1 is a plan view illustrating a semiconductor device according to a first embodiment.

FIG. 2 is a cross-sectional view illustrating the semiconductor device according to the first embodiment.

FIG. 2 is a cross-sectional view at the position of line II-II shown in FIG. 1.

As illustrated in FIGS. 1 and 2, the semiconductor device 100 according to the first embodiment includes a lead frame 10, a first solder layer 20, a semiconductor element 30, and a sealing resin layer 40.

In the following description, the direction from the lead frame 10 toward the semiconductor element 30 is called “up”, and the direction from the semiconductor element 30 toward the lead frame 10 is called “down”.

The lead frame 10 is positioned at the lower portion of the semiconductor device 100. The first solder layer 20 is located on the lead frame 10. The semiconductor element 30 is located on the first solder layer 20. The sealing resin layer 40 is located on the semiconductor element 30 and the lead frame 10.

The lead frame 10 includes a first base part 11, a first barrier metal layer 12, and a first adhesion layer 13. The first base part 11 is positioned at the lower portion of the lead frame 10. The first barrier metal layer 12 is located on the first base part 11. The first barrier metal layer 12 is located at least at the surface of the first base part 11 at the side at which the semiconductor element 30 is mounted. The first adhesion layer 13 is located on the first barrier metal layer 12. The first adhesion layer 13 is located at least on the first barrier metal layer 12 located at the surface of the first base part 11 at the side at which the semiconductor element 30 is mounted.

For example, the first base part 11 has a flat plate shape. The first base part 11 includes a metal. The first base part 11 includes, for example, copper (Cu).

For example, the first barrier metal layer 12 has a flat plate shape (a film shape). The first barrier metal layer 12 covers a portion of the first base part 11, and favorably the entire surface where a plane contacts the plate-shaped first base part 11. For example, the first barrier metal layer 12 covers the entire surface of the first base part 11 when viewed in plan. The first barrier metal layer 12 includes a metal having a diffusion rate into solder that is less than that of copper. The diffusion rate is the movement speed when solder is in a liquid state or a solid state. The first barrier metal layer 12 includes, for example, at least one selected from the group consisting of nickel (Ni), chrome (Cr), and titanium (Ti). It is favorable for the first barrier metal layer 12 to include, for example, nickel. For example, the first barrier metal layer 12 functions as a barrier metal layer suppressing contact of the first solder layer 20 with the first base part 11.

The first barrier metal layer 12 includes a first solder region 12a and a first sealing region 12b. The first solder region 12a overlaps the first solder layer 20 and the semiconductor element 30 in the vertical direction. The first sealing region 12b does not overlap the first solder layer 20 and the semiconductor element 30 in the vertical direction. The first sealing region 12b is, for example, a region of the first barrier metal layer 12 other than the first solder region 12a. For example, the first sealing region 12b surrounds at least a portion around the first solder region 12a, and more favorably the entire first solder region 12a when viewed in plan.

A thickness T1 of the first barrier metal layer 12 is, for example, not less than 0.05 μm and not more than 5 μm. The thickness of the first solder region 12a is, for example, equal to the thickness of the first sealing region 12b, and may be less than the thickness of the first sealing region 12b in some cases. The thickness T1 of the first barrier metal layer 12 is, for example, equal to the thickness of the first solder region 12a and the thickness of the first sealing region 12b. The thickness T1 of the first barrier metal layer 12 may be, for example, equal to the thickness of the first sealing region 12b and greater than the thickness of the first solder region 12a.

The first adhesion layer 13 is located on the first sealing region 12b. For example, the first adhesion layer 13 covers the entire surface of the first sealing region 12b when viewed in plan. The first adhesion layer 13 is positioned above the first barrier metal layer 12 in the vertical direction and covers a portion, and more favorably the entire surface, of the first barrier metal layer 12 that does not overlap the first solder layer 20 and the semiconductor element 30. The first adhesion layer 13 covers a portion, and more favorably the entire surface, of the first barrier metal layer 12 that does not overlap the semiconductor element 30. The first adhesion layer 13 is positioned at a portion of the first solder layer 20 and more specifically, the side of the first solder layer 20 at the first barrier metal layer 12 side. For example, the first adhesion layer 13 surrounds a portion around the first solder layer 20, and more favorably, the entire first solder layer 20 when viewed in plan. For example, the first adhesion layer 13 has a plate shape (a film shape) with a through-hole extending through in the vertical direction. The first adhesion layer 13 has a plate shape (a film shape) with a through-hole extending through in the direction from the first base part 11 toward the semiconductor element 30. The first solder layer 20 is positioned inside the through-hole. The first adhesion layer 13 includes, for example, a metal material having a diffusion rate into the first solder layer 20 that is greater than that of the first barrier metal layer 12. The first adhesion layer 13 includes, for example, copper.

A thickness T2 of the first adhesion layer 13 is, for example, not less than 0.05 μm and not more than 2 μm. It is favorable for the thickness T2 of the first adhesion layer 13 to be not more than 1.5 μm, and more favorably not more than 1.0 μm. The thickness T2 of the first adhesion layer 13 is, for example, less than the thickness of the first solder layer 20. The thickness T2 of the first adhesion layer 13 is, for example, less than the thickness T1 of the first barrier metal layer 12.

The first adhesion layer 13 includes an upper surface 13x and a lower surface 13y. The upper surface 13x contacts the sealing resin layer 40. The lower surface 13y contacts the first barrier metal layer 12. It is favorable for the upper surface 13x to be roughened. The roughening is described below.

The first solder layer 20 is located on the first solder region 12a of the first barrier metal layer 12. The first solder layer 20 is material supplied in a form such as solder paste, a solder sheet, a solder wire, etc., and is formed by solder bonding by heat processing. The first solder layer 20 includes solder. The first solder layer 20 may be pre-formed on the back surface of the semiconductor element 30, and may be mounted and bonded to the heated lead frame 10. For example, the first solder layer 20 at the back surface of the semiconductor element 30 is formed in the wafer state before singulating the semiconductor elements 30. The first solder layer 20 includes, for example, lead-free solder. The first solder layer 20 includes, for example, at least one selected from the group consisting of tin, silver, copper, antimony, nickel, and bismuth. The first solder layer 20 may include, for example, solder including lead. Even when the first solder layer 20 includes solder including lead, effects similar to those when the first solder layer 20 includes lead-free solder are obtained.

The semiconductor element 30 is located on the first solder layer 20. The first solder layer 20 is located between the first barrier metal layer 12 and the semiconductor element 30. The semiconductor element 30 is located on the first solder region 12a of the first barrier metal layer 12 with the first solder layer 20 interposed. The semiconductor element 30 is, for example, a power semiconductor element that controls and/or converts power. The semiconductor element 30 includes, for example, at least one of a bipolar transistor, an IGBT (Insulated Gate Bipolar Transistor), or a MOSFET (Metal Oxide Semiconductor Field Effect Transistor).

The sealing resin layer 40 is located on the semiconductor element 30 and on the first adhesion layer 13. The sealing resin layer 40 is located at least at the surface of the lead frame 10 at the side at which the semiconductor element 30 is mounted. The sealing resin layer 40 covers at least a portion or the entire surface of the semiconductor element 30 and the lead frame 10. In other words, the sealing resin layer 40 is located at a portion of the surface of the lead frame 10 to which the semiconductor element 30 is solder-bonded with the first adhesion layer 13 interposed. More specifically, the sealing resin layer 40 is located at a portion of the periphery of the solder bonding portion of the lead frame 10 with the first adhesion layer 13 interposed. More favorably, the sealing resin layer 40 is located at the surface of the lead frame 10 to which the semiconductor element 30 is solder-bonded with the first adhesion layer 13 interposed. A portion of the sealing resin layer 40 is positioned at the side of the semiconductor element 30 and the side of the first solder layer 20. The sealing resin layer 40 contacts the upper surface 13x of the first adhesion layer 13. The sealing resin layer 40 includes, for example, a thermosetting resin. The sealing resin layer 40 includes, for example, at least one selected from the group consisting of an epoxy resin and a silicone gel.

It is favorable for the average void fraction of the first solder layer 20 to be less than 2.5%. It is more favorable for the average void fraction of the first solder layer 20 to be not more than 1.3%.

Although not illustrated in FIG. 2, for example, a connection member that connects the lead frame 10 and a front electrode of the semiconductor element 30 is located on the semiconductor element 30. The connection member may be, for example, a bonding wire or a connector. The connector is, for example, a copper plate.

A portion of the first solder layer 20 may not overlap the semiconductor element 30 in the vertical direction. In other words, a portion of the first solder layer 20 may jut from the semiconductor element 30 when viewed in plan. For example, the first solder layer 20 may exude and jut from the semiconductor element 30.

In addition to the first barrier metal layer 12 and the first adhesion layer 13, the lead frame 10 also may include another layer. The other layer may be located between the first base part and the first barrier metal layer 12, and/or may be located between the first barrier metal layer 12 and the first adhesion layer 13. The other layer may be one, two, or more layers.

Effects of the semiconductor device according to the embodiment will now be described.

In a known semiconductor device, a semiconductor element is bonded to a lead frame via a solder layer; and the semiconductor element is sealed with a sealing resin. In such a semiconductor device, it is desirable to realize both high-temperature reliability of the solder bonding portion and adhesion between the lead frame and the sealing resin.

In particular, when the solder layer includes lead-free solder, there are cases where high-temperature reliability problems occur such as voids occurring between the solder layer and the lead frame, the solder layer detaching from the lead frame, etc., when left for a long period of time at a high temperature. As a technique of increasing the high-temperature reliability of the solder bonding portion, it may be considered to provide a metal layer including a metal such as nickel, etc., on the lead frame and to bond the semiconductor element on the metal layer via a solder layer. When, however, such a metal layer is provided, there are cases where the adhesion between the sealing resin and the lead frame including the metal layer may degrade. In particular, it is desirable to realize both the high-temperature reliability of the solder bonding portion and the adhesion between the lead frame and the sealing resin for a semiconductor device in which the solder layer includes lead-free solder.

In the semiconductor device 100 according to the embodiment, in the lead frame 10, the first barrier metal layer 12 is located on the first base part 11, and the first adhesion layer 13 is located on the first barrier metal layer 12; the first solder layer 20 contacts the first barrier metal layer 12; and the sealing resin layer 40 contacts the first adhesion layer 13. The high-temperature reliability of the solder bonding portion can be increased by the first solder layer 20 contacting the first barrier metal layer 12. Also, by providing the first barrier metal layer 12 between the first base part 11 and the first solder layer 20, diffusion of metal from the first base part 11 to the first solder layer 20 can be suppressed. For example, by forming the first adhesion layer 13 not only on the first solder region 12a of the first barrier metal layer 12 overlapping the first solder layer 20 but also on the first sealing region 12b that does not overlap the first solder layer 20, the first adhesion layer 13 can remain on the first sealing region 12b after the formation of the first solder layer 20. By the sealing resin layer 40 contacting the first adhesion layer 13, the adhesion between the lead frame 10 and the sealing resin layer 40 can be improved. Accordingly, both the high-temperature reliability of the solder bonding portion and the adhesion between the lead frame 10 and the sealing resin layer 40 can be realized.

By setting the thickness T1 of the first barrier metal layer 12 to be not less than 0.05 μm, the contact of the first solder layer 20 with the first base part 11 can be more reliably suppressed, and the first barrier metal layer 12 can function more reliably as a barrier metal layer. By setting the thickness T1 of the first barrier metal layer 12 to be not more than 5 μm, the stress when forming the first barrier metal layer 12 is prevented from becoming too large, and so degradation of the adhesion between the first barrier metal layer 12 and the first base part 11 can be suppressed, warp of the semiconductor device 100 can be suppressed, etc. Also, the first barrier metal layer 12 can be formed more easily.

By the first barrier metal layer 12 including at least one selected from the group consisting of nickel, chrome, and titanium, the diffusion rate of the first barrier metal layer 12 into the first solder layer 20 can be more reliably set to be less than the diffusion rate of the first adhesion layer 13 into the first solder layer 20. As a result, in the solder bonding process, the first barrier metal layer 12 can be prevented from dissolving into the first solder layer 20; and the first barrier metal layer 12 can be prevented from disappearing.

By setting the thickness T2 of the first adhesion layer 13 to be not less than 0.05 μm, contact of the sealing resin layer 40 with the first barrier metal layer 12 can be more reliably suppressed, and the adhesion between the lead frame 10 and the sealing resin layer 40 can be more reliably improved. By setting the thickness T2 of the first adhesion layer 13 to be not more than 2 μm, the effects of characteristic degradation of the wettability of molten solder, etc., in the solder bonding process can be suppressed even when the first adhesion layer 13 dissolves in the first solder layer 20; and the solder bondability can be maintained. Also, the first adhesion layer 13 can be formed more easily.

By roughening the upper surface 13x of the first adhesion layer 13, the adhesion between the sealing resin layer 40 and the upper surface 13x of the first adhesion layer 13 can be improved. As a result, the adhesion between the lead frame 10 and the sealing resin layer 40 can be further improved.

### Second Embodiment

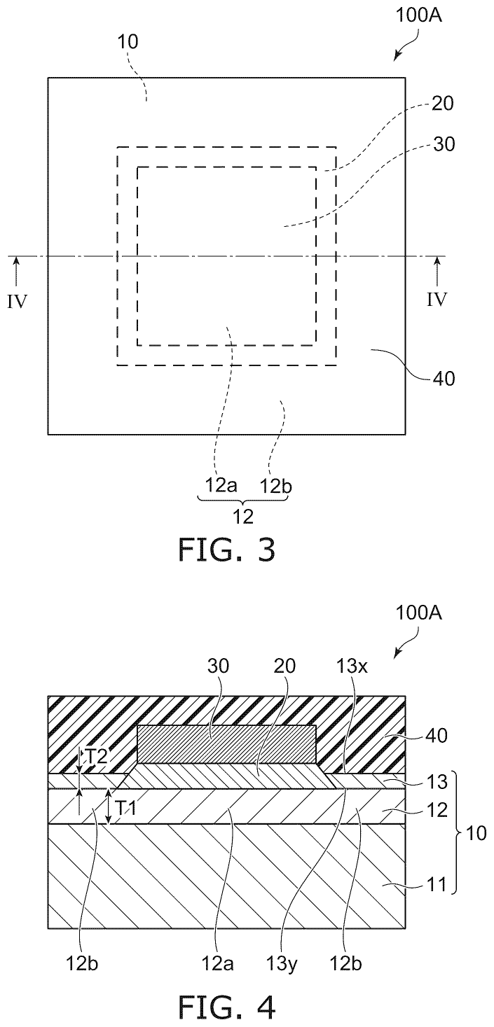

FIG. 3 is a plan view illustrating a semiconductor device according to a second embodiment.

FIG. 4 is a cross-sectional view illustrating the semiconductor device according to the second embodiment.

FIG. 4 is a cross-sectional view at the position of line IV-IV shown in FIG. 3.

As illustrated in FIGS. 3 and 4, other than the shape of the first solder layer 20 being different, the semiconductor device 100A according to the second embodiment is the same as the semiconductor device 100 according to the first embodiment.

In the semiconductor device 100A, a portion of the first solder layer 20 juts from the semiconductor element 30 when viewed in plan. Thus, the first solder layer 20 may jut from at least one side of the semiconductor element 30 when viewed in plan. In the example of FIGS. 3 and 4, the first solder layer 20 juts from four sides of the semiconductor element 30 when viewed in plan. In the example of FIGS. 3 and 4, the area of the first solder layer 20 is greater than the area of the semiconductor element 30 when viewed in plan.

For example, when manufacturing the semiconductor device, the first solder layer 20 is provided in a wider area (e.g., the entire surface) of the lower surface of the semiconductor element 30 to more reliably bond the semiconductor element 30 to the lead frame 10. In such a case, as illustrated in FIGS. 3 and 4, there are cases where a portion of the first solder layer 20 juts from the semiconductor element 30.

In the semiconductor device 100A as well, by providing the first solder layer 20 to contact the first barrier metal layer 12, the high-temperature reliability of the solder bonding portion can be increased. By providing the first barrier metal layer 12 between the first base part 11 and the first solder layer 20, diffusion of metal from the first base part 11 into the solder layer 20 can be suppressed. By providing the sealing resin layer 40 to contact the first adhesion layer 13, the adhesion between the lead frame 10 and the sealing resin layer 40 can be improved. Accordingly, both the high-temperature reliability of the solder bonding portion and the adhesion between the lead frame 10 and the sealing resin layer 40 can be realized.

### Third Embodiment

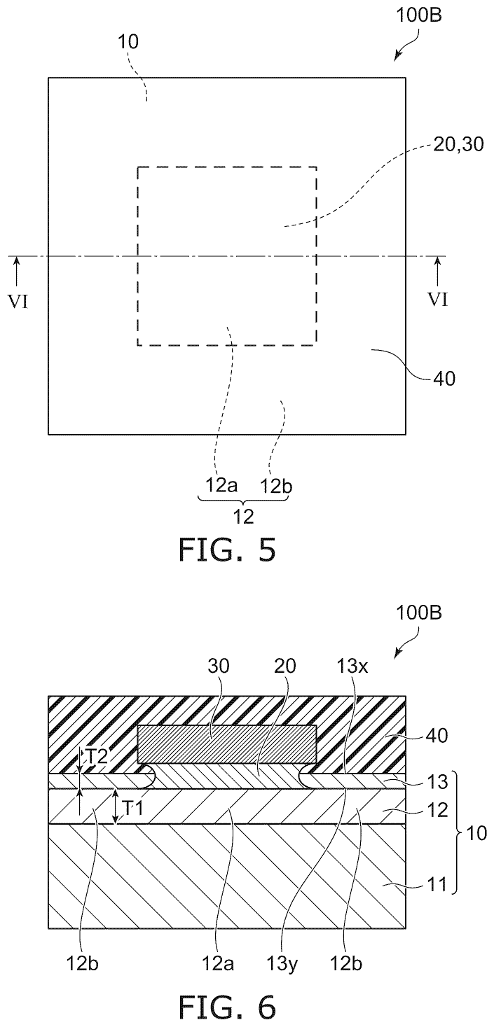

FIG. 5 is a plan view illustrating a semiconductor device according to a third embodiment.

FIG. 6 is a cross-sectional view illustrating the semiconductor device according to the third embodiment.

FIG. 6 is a cross-sectional view at the position of line VI-VI shown in FIG. 5.

As illustrated in FIGS. 5 and 6, other than the shape of the first solder layer 20 being different, the semiconductor device 100B according to the third embodiment is the same as the semiconductor device 100 according to the first embodiment.

In the semiconductor device 100B, the first solder layer 20 is drum-shaped when viewed in cross-section. In the semiconductor device 100B, the side surface of the first solder layer 20 is pinched-in. In the example of FIGS. 5 and 6, the side surface of the first solder layer 20 is curved to be inwardly convex. In the semiconductor device 100B, the area at the upper end of the first solder layer 20 and the area at the lower end of the first solder layer 20 are greater than the area at a position between the upper end and the lower end of the first solder layer 20 when viewed in plan.

For example, when manufacturing the semiconductor device, when the first solder layer 20 is formed and bonded at the bonding surface, there are cases where the shape of the first solder layer 20 becomes drum-shaped due to the volume of the first solder layer 20 decreasing when the first solder layer 20 solidifies.

In the semiconductor device 100B as well, the high-temperature reliability of the solder bonding portion can be increased by providing the first solder layer 20 to contact the first barrier metal layer 12. By providing the first barrier metal layer 12 between the first base part 11 and the first solder layer 20, diffusion of metal from the first base part 11 into the first solder layer 20 can be suppressed. By providing the sealing resin layer 40 to contact the first adhesion layer 13, the adhesion between the lead frame 10 and the sealing resin layer 40 can be improved. Accordingly, both the high-temperature reliability of the solder bonding portion and the adhesion between the lead frame 10 and the sealing resin layer 40 can be realized. In the semiconductor device 100B, because the first solder layer 20 is drum-shaped, the sealing resin layer 40 easily extends into the first solder layer 20. Accordingly, mechanical detachment of the sealing resin layer 40 does not occur easily.

### Fourth Embodiment

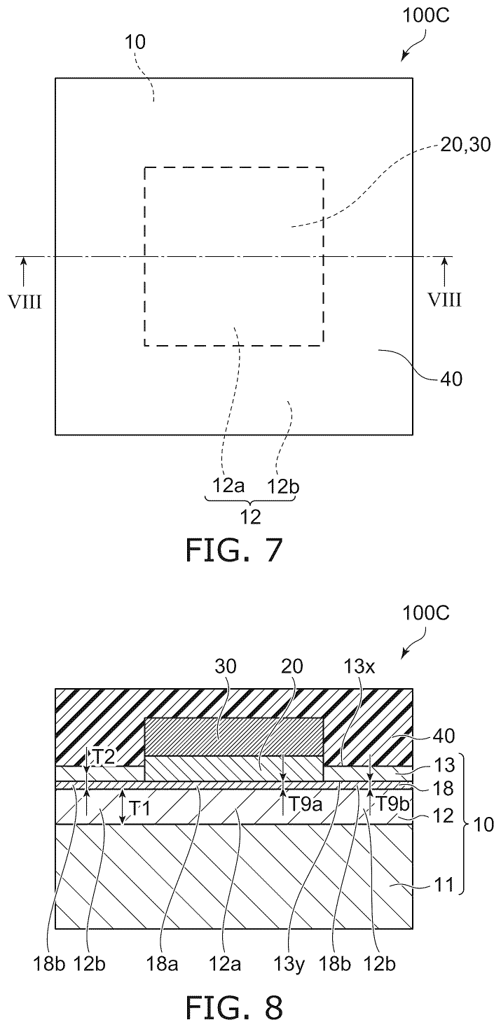

FIG. 7 is a plan view illustrating a semiconductor device according to a fourth embodiment.

FIG. 8 is a cross-sectional view illustrating the semiconductor device according to the fourth embodiment.

FIG. 8 is a cross-sectional view at the position of line VIII-VIII shown in FIG. 7.

As illustrated in FIGS. 7 and 8, other than the lead frame 10 further including an intermediate metal layer 18, the semiconductor device 100C according to the fourth embodiment is the same as the semiconductor device 100 according to the first embodiment.

In the semiconductor device 100C, the lead frame 10 further includes the intermediate metal layer 18. The intermediate metal layer 18 includes, for example, a first intermediate region 18a and a second intermediate region 18b. The first intermediate region 18a is positioned between the first barrier metal layer 12 and the first solder layer 20. More specifically, the first intermediate region 18a is positioned between the first solder layer 20 and the first solder region 12a of the first barrier metal layer 12. The second intermediate region 18b is positioned between the first barrier metal layer 12 and the first adhesion layer 13. More specifically, the second intermediate region 18b is positioned between the first adhesion layer 13 and the first sealing region 12b of the first barrier metal layer 12.

For example, the intermediate metal layer 18 has a flat plate shape (a film shape). The intermediate metal layer 18 includes, for example, at least one selected from the group consisting of silver (Ag), titanium (Ti), and palladium (Pd).

A thickness T9a of the first intermediate region 18a is, for example, not more than 1.0 μm. A thickness T9b of the second intermediate region 18b is, for example, not less than 0.1 μm and not more than 1.0 μm. The thickness T9a of the first intermediate region 18a is, for example, equal to the thickness T9b of the second intermediate region 18b. The thickness T9a of the first intermediate region 18a may be, for example, less than the thickness T9b of the second intermediate region 18b. The thickness T9a of the first intermediate region 18a and the thickness T9b of the second intermediate region 18b are, for example, about equal to the thickness T2 of the first adhesion layer 13 or less than the thickness T2 of the first adhesion layer 13.

The first intermediate region 18a may be provided over the entire surface between the first barrier metal layer 12 and the first solder layer 20, and may be provided at a portion between the first barrier metal layer 12 and the first solder layer 20. The second intermediate region 18b may be provided over the entire surface between the first barrier metal layer 12 and the first adhesion layer 13, or may be provided at a portion between the first barrier metal layer 12 and the first adhesion layer 13. For example, a portion of the intermediate metal layer 18 or the entire intermediate metal layer 18 that is included in the substrate (a substrate 200 described below) before bonding the semiconductor element 30 may disappear due to heating when bonding.

In the semiconductor device 100C as well, by providing the first solder layer 20 to contact the first barrier metal layer 12, the high-temperature reliability of the solder bonding portion can be increased. By providing the first barrier metal layer 12 between the first base part 11 and the first solder layer 20, diffusion of metal from the first base part 11 into the first solder layer 20 can be suppressed. By providing the sealing resin layer 40 to contact the first adhesion layer 13, the adhesion between the lead frame 10 and the sealing resin layer 40 can be improved. Accordingly, both the high-temperature reliability of the solder bonding portion and the adhesion between the lead frame 10 and the sealing resin layer 40 can be realized. In the semiconductor device 100C, by providing the intermediate metal layer 18 on the first barrier metal layer 12, oxidization of the first barrier metal layer 12 can be suppressed, and the first barrier metal layer 12 can easily function as a barrier metal layer. Also, by providing the intermediate metal layer 18 on the first barrier metal layer 12, the solder wettability can be improved.

### Fifth Embodiment

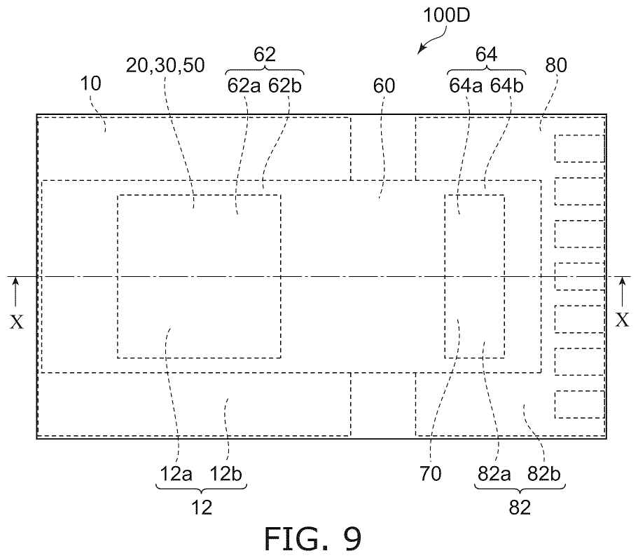

FIG. 9 is a plan view illustrating a semiconductor device according to a fifth embodiment.

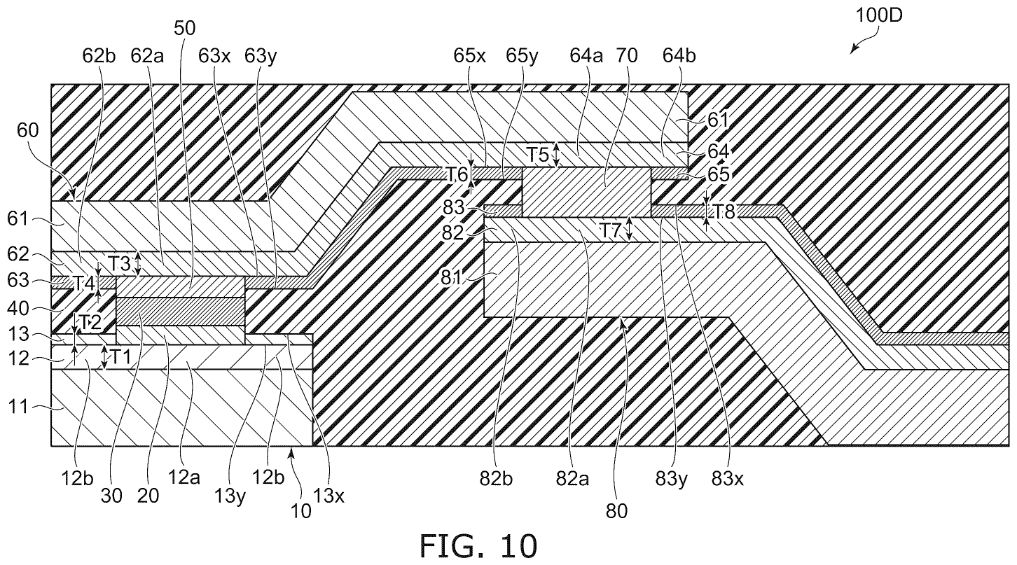

FIG. 10 is a cross-sectional view illustrating the semiconductor device according to the fifth embodiment.

FIG. 10 is a cross-sectional view at the position of line X-X shown in FIG. 9.

As illustrated in FIGS. 9 and 10, other than including a connector 60 that includes a metal layer, the semiconductor device 100D according to the fifth embodiment is the same as the semiconductor device 100 according to the first embodiment.

A second solder layer 50 is located on the semiconductor element 30. The connector 60 is located on the second solder layer 50. That is, the connector 60 is located on the semiconductor element 30 with the second solder layer 50 interposed.

The connector 60 includes a second base part 61, a second barrier metal layer 62, and a second adhesion layer 63. The second base part 61 is positioned at the upper portion of the connector 60. The second barrier metal layer 62 is located under the second base part 61. The second barrier metal layer 62 is located at least at the surface of the second base part 61 at the side facing the semiconductor element 30. The second adhesion layer 63 is located under the second barrier metal layer 62. The second adhesion layer 63 is located at least under the second barrier metal layer 62 located at the surface of the second base part 61 at the side facing the semiconductor element 30.

For example, the second base part 61 has a flat plate shape. The second base part 61 includes a metal. The second base part 61 includes, for example, copper (Cu).

For example, the second barrier metal layer 62 has a flat plate shape (a film shape). The second barrier metal layer 62 covers a portion of the second base part 61, and favorably the entire surface where a plane contacts the plate-shaped second base part 61. The second barrier metal layer 62 includes a metal having a diffusion rate into solder that is less than that of copper. The second barrier metal layer 62 includes, for example, at least one selected from the group consisting of nickel (Ni), chrome (Cr), and titanium (Ti). It is favorable for the second barrier metal layer 62 to include, for example, nickel. For example, the second barrier metal layer 62 functions as a barrier metal layer suppressing contact of the second solder layer 50 with the second base part 61.

The second barrier metal layer 62 includes a second solder region 62a and a second sealing region 62b. The second solder region 62a overlaps the second solder layer 50 and the semiconductor element 30 in the vertical direction. The second sealing region 62b does not overlap the second solder layer 50 and the semiconductor element 30 in the vertical direction. The second sealing region 62b is, for example, a region of the second barrier metal layer 62 other than the second solder region 62a. For example, the second sealing region 62b surrounds at least a portion around the second solder region 62a, and more favorably the entire second solder region 62a when viewed in plan.

A thickness T3 of the second barrier metal layer 62 is, for example, not less than 0.05 μm and not more than 5 μm. The thickness of the second solder region 62a is, for example, equal to the thickness of the second sealing region 62b, or less than the thickness of the second sealing region 62b in some cases. The thickness T3 of the second barrier metal layer 62 is, for example, equal to the thickness of the second solder region 62a and the thickness of the second sealing region 62b. The thickness T3 of the second barrier metal layer 62 may be, for example, equal to the thickness of the second sealing region 62b and greater than the thickness of the second solder region 62a.

The second adhesion layer 63 is positioned below the second barrier metal layer 62 in the vertical direction and covers a portion, and more favorably the entire surface of the second barrier metal layer 62 not overlapping the second solder layer 50 and the semiconductor element 30. The second adhesion layer 63 covers a portion, and more favorably the entire surface of the second barrier metal layer 62 not overlapping the semiconductor element 30. The second adhesion layer 63 is positioned at a portion of the second solder layer 50, and more specifically, the side of the second solder layer 50 at the second barrier metal layer 62 side. For example, the second adhesion layer 63 surrounds a portion around the second solder layer 50, and more favorably the entire second solder layer 50 when viewed in plan. For example, the second adhesion layer 63 has a plate shape (a film shape) having a through-hole extending through in the vertical direction. The second adhesion layer 63 has a plate shape (a film shape) having a through-hole extending through in the direction from the second base part 61 toward the semiconductor element 30. The second solder layer 50 is positioned inside the through-hole. The second adhesion layer 63 includes, for example, a metal material having a diffusion rate into the second solder layer 50 that is greater than that of the second barrier metal layer 62. The second adhesion layer 63 includes, for example, copper.

A thickness T4 of the second adhesion layer 63 is, for example, not less than 0.05 μm and not more than 2 μm. It is favorable for the thickness T4 of the second adhesion layer 63 to be not more than 1.5 μm, and more favorably not more than 1.0 μm. The thickness T4 of the second adhesion layer 63 is, for example, less than the thickness of the first solder layer 20. The thickness T4 of the second adhesion layer 63 is, for example, less than the thickness T3 of the second barrier metal layer 62.

The second adhesion layer 63 includes an upper surface 63x and a lower surface 63y. The lower surface 63y contacts the sealing resin layer 40. The upper surface 63x contacts the second barrier metal layer 62. It is favorable for the lower surface 63y to be roughened. The roughening is described below.

In the example of FIGS. 9 and 10, the second barrier metal layer 62 and the second adhesion layer 63 are located only under the second base part 61. The second barrier metal layer 62 and the second adhesion layer 63 also may be located on the second base part 61. That is, the second barrier metal layer 62 and the second adhesion layer 63 may be located at two surfaces of the second base part 61. The second adhesion layer 63 that is on the second base part 61 is located on the second barrier metal layer 62. Compared to when, for example, the second barrier metal layer 62 is located at two surfaces and the second adhesion layer 63 is located at one surface, the adhesion with the sealing resin layer 40 can be improved, the manufacturing can be easy, and the cost can be reduced by providing the second barrier metal layer 62 and the second adhesion layer 63 at two surfaces of the second base part 61.

The second solder layer 50 is located under the second solder region 62a of the second barrier metal layer 62. The second solder layer 50 is located between the second barrier metal layer 62 and the semiconductor element 30. The semiconductor element 30 is located under the second solder region 62a of the second barrier metal layer 62 with the second solder layer 50 interposed. The second solder layer 50 is formed by supplying material in a form such as solder paste, a solder sheet, a solder wire, etc., and by solder bonding by heat processing. The second solder layer 50 includes solder. The second solder layer 50 includes, for example, lead-free solder. The second solder layer 50 includes, for example, at least one selected from the group consisting of tin, silver, copper, antimony, nickel, and bismuth. The second solder layer 50 also may include, for example, solder including lead. Even when the second solder layer 50 includes solder including lead, effects similar to when the second solder layer 50 includes lead-free solder are obtained.

The semiconductor device 100D further includes a third solder layer 70 and a connection frame 80. The third solder layer 70 is located between the connection frame 80 and the connector 60.

In the semiconductor device 100D, the connector 60 is located on the third solder layer 70. That is, the connector 60 is located on the connection frame 80 with the third solder layer 70 interposed.

The connector 60 further includes a third barrier metal layer 64 and a third adhesion layer 65. The third barrier metal layer 64 is located under the second base part 61. The third barrier metal layer 64 is located at least at the surface of the second base part 61 at the side facing the third solder layer 70. The third adhesion layer 65 is located under the third barrier metal layer 64. The third adhesion layer 65 is located at least under the third barrier metal layer 64 located at the surface of the second base part 61 at the side facing the third solder layer 70.

For example, the third barrier metal layer 64 has a flat plate shape (a film shape). The third barrier metal layer 64 covers a portion of the second base part 61, and favorably the entire surface where a plane contacts the plate-shaped second base part 61. The third barrier metal layer 64 includes a metal having a diffusion rate into solder that is less than that of copper. The third barrier metal layer 64 includes, for example, at least one selected from the group consisting of nickel (Ni), chrome (Cr), and titanium (Ti). It is favorable for the third barrier metal layer 64 to include, for example, nickel. For example, the third barrier metal layer 64 functions as a barrier metal layer suppressing contact of the third solder layer 70 with the second base part 61.

The third barrier metal layer 64 includes a third solder region 64a and a third sealing region 64b. The third solder region 64a overlaps the third solder layer 70 in the vertical direction. The third sealing region 64b does not overlap the third solder layer 70 in the vertical direction. The third sealing region 64b is, for example, a region of the third barrier metal layer 64 other than the third solder region 64a. For example, the third sealing region 64b surrounds at least a portion around the third solder region 64a, and more favorably the entire third solder region 64a when viewed in plan.

A thickness T5 of the third barrier metal layer 64 is, for example, not less than 0.05 μm and not more than 5 μm. The thickness of the third solder region 64a is, for example, equal to the thickness of the third sealing region 64b, or may be less than the thickness of the third sealing region 64b in some cases. The thickness T5 of the third barrier metal layer 64 is, for example, equal to the thickness of the third solder region 64a and the thickness of the third sealing region 64b. The thickness T5 of the third barrier metal layer 64 may be, for example, equal to the thickness of the third sealing region 64b and greater than the thickness of the third solder region 64a.

The third adhesion layer 65 is positioned below the third barrier metal layer 64 in the vertical direction and covers a portion, and more favorably the entire surface of the third barrier metal layer 64 not overlapping the third solder layer 70. The third adhesion layer 65 covers a portion, and more favorably the entire surface of the third barrier metal layer 64 not overlapping the third solder layer 70. The third adhesion layer 65 is positioned at a portion of the third solder layer 70, and more specifically, at the side of the third solder layer 70 at the third barrier metal layer 64 side. For example, the third adhesion layer 65 surrounds a portion around the third solder layer 70, and more favorably the entire third solder layer 70 when viewed in plan. For example, the third adhesion layer 65 has a plate shape (a film shape) having a through-hole extending through in the vertical direction. The third adhesion layer 65 has a plate shape (a film shape) having a through-hole extending through in the direction from the second base part 61 toward the third solder layer 70. The third solder layer 70 is positioned inside the through-hole. The third adhesion layer 65 includes, for example, a metal material having a diffusion rate into the third solder layer 70 that is greater than that of the third barrier metal layer 64. The third adhesion layer 65 includes, for example, copper.

A thickness T6 of the third adhesion layer 65 is, for example, not less than 0.05 μm and not more than 2 μm. It is favorable for the thickness T6 of the third adhesion layer 65 to be not more than 1.5 μm, and more favorably not more than 1.0 μm. The thickness T6 of the third adhesion layer 65 is, for example, less than the thickness of the third solder layer 70. The thickness T6 of the third adhesion layer 65 is, for example, less than the thickness T5 of the third barrier metal layer 64.

The third adhesion layer 65 includes an upper surface 65x and a lower surface 65y. The lower surface 65y contacts the sealing resin layer 40. The upper surface 65x contacts the third barrier metal layer 64. It is favorable for the lower surface 65y to be roughened. The roughening is described below.

In the example of FIGS. 9 and 10, the third barrier metal layer 64 and the third adhesion layer 65 are located only under the second base part 61. The third barrier metal layer 64 and the third adhesion layer 65 also may be located on the second base part 61. That is, the third barrier metal layer 64 and the third adhesion layer 65 may be located at two surfaces of the second base part 61. The third adhesion layer 65 that is on the second base part 61 is located on the third barrier metal layer 64. Compared to, for example, when the third barrier metal layer 64 is located at two surfaces and the third adhesion layer 65 is located at one surface, the adhesion with the sealing resin layer 40 can be improved, the manufacturing can be easy, and the cost can be reduced by providing the third barrier metal layer 64 and the third adhesion layer 65 at two surfaces of the second base part 61.

The third solder layer 70 is located under the third solder region 64a of the third barrier metal layer 64. The third solder layer 70 is formed by supplying a material in a form such as solder paste, a solder sheet, a solder wire, etc., and by solder bonding by heat processing. The third solder layer 70 includes solder. The third solder layer 70 includes, for example, lead-free solder. The third solder layer 70 includes, for example, at least one selected from the group consisting of tin, silver, copper, antimony, nickel, and bismuth. The third solder layer 70 also may include, for example, solder including lead. Even when the third solder layer 70 includes solder including lead, effects similar to those when the third solder layer 70 includes lead-free solder are obtained.

In the example of FIGS. 9 and 10, the third barrier metal layer 64 is continuous with the second barrier metal layer 62. The third barrier metal layer 64 may not be continuous with the second barrier metal layer 62. In the example of FIG. 10, the third adhesion layer 65 is continuous with the second adhesion layer 63. The third adhesion layer 65 may not be continuous with the second adhesion layer 63.

The connection frame 80 further includes a third base part 81, a fourth barrier metal layer 82, and a fourth adhesion layer 83. The fourth barrier metal layer 82 is located on the third base part 81. The fourth barrier metal layer 82 is located at least at the surface of the third base part 81 at the side facing the third solder layer 70. The fourth adhesion layer 83 is located on the fourth barrier metal layer 82. The fourth adhesion layer 83 is located at least on the fourth barrier metal layer 82 located at the surface of the third base part 81 at the side facing the third solder layer 70.

For example, the fourth barrier metal layer 82 has a flat plate shape (a film shape). The fourth barrier metal layer 82 covers a portion of the third base part 81, and favorably the entire surface where a plane contacts the plate-shaped third base part 81. The fourth barrier metal layer 82 includes a metal having a diffusion rate into solder that is less than that of copper. The fourth barrier metal layer 82 includes, for example, at least one selected from the group consisting of nickel (Ni), chrome (Cr), and titanium (Ti). It is favorable for the fourth barrier metal layer 82 to include, for example, nickel. For example, the fourth barrier metal layer 82 functions as a barrier metal layer suppressing contact of the third solder layer 70 with the third base part 81.

The fourth barrier metal layer 82 includes a fourth solder region 82a and a fourth sealing region 82b. The fourth solder region 82a overlaps the third solder layer 70 in the vertical direction. The fourth sealing region 82b does not overlap the third solder layer 70 in the vertical direction. The fourth sealing region 82b is, for example, a region of the fourth barrier metal layer 82 other than the fourth solder region 82a. For example, the fourth sealing region 82b surrounds at least a portion around the fourth solder region 82a, and more favorably the entire fourth solder region 82a when viewed in plan.

A thickness T7 of the fourth barrier metal layer 82 is, for example, not less than 0.05 μm and not more than 5 μm. The thickness of the fourth solder region 82a is, for example, equal to the thickness of the fourth sealing region 82b, or less than the thickness of the fourth sealing region 82b in some cases. The thickness T7 of the fourth barrier metal layer 82 is, for example, equal to the thickness of the fourth solder region 82a and the thickness of the fourth sealing region 82b. The thickness T7 of the fourth barrier metal layer 82 may be, for example, equal to the thickness of the fourth sealing region 82b and greater than the thickness of the fourth solder region 82a.

The fourth adhesion layer 83 is positioned above the fourth barrier metal layer 82 in the vertical direction and covers a portion, and more favorably the entire surface of the fourth barrier metal layer 82 not overlapping the third solder layer 70. The fourth adhesion layer 83 covers a portion, and more favorably the entire surface of the fourth barrier metal layer 82 not overlapping the third solder layer 70. The fourth adhesion layer 83 is positioned at a portion of the third solder layer 70, and more specifically, the side of the third solder layer 70 at the fourth barrier metal layer 82 side. For example, the fourth adhesion layer 83 surrounds a portion around the third solder layer 70, and more favorably the entire third solder layer 70 when viewed in plan. For example, the fourth adhesion layer 83 has a plate shape (a film shape) having a through-hole extending through in the vertical direction. The fourth adhesion layer 83 has a plate shape (a film shape) having a through-hole extending through in the direction from the third base part 81 toward the third solder layer 70. The third solder layer 70 is positioned inside the through-hole. The fourth adhesion layer 83 includes, for example, a metal material having a diffusion rate into the third solder layer 70 that is greater than that of the fourth barrier metal layer 82. The fourth adhesion layer 83 includes, for example, copper.

A thickness T8 of the fourth adhesion layer 83 is, for example, not less than 0.05 μm and not more than 2 μm. It is favorable for the thickness T8 of the fourth adhesion layer 83 to be not more than 1.5 μm, and more favorably not more than 1.0 μm. The thickness T8 of the fourth adhesion layer 83 is, for example, less than the thickness of the third solder layer 70. The thickness T8 of the fourth adhesion layer 83 is, for example, less than the thickness T7 of the fourth barrier metal layer 82.

The fourth adhesion layer 83 includes an upper surface 83x and a lower surface 83y. The upper surface 83x contacts the sealing resin layer 40. The lower surface 83y contacts the fourth barrier metal layer 82. It is favorable for the upper surface 83x to be roughened. The roughening is described below.

Although FIGS. 9 and 10 illustrate a case where the connection frame 80 is connected to the connector 60 via the third solder layer 70, the third solder layer 70 and the connection frame 80 may be omitted. In such a case, the connector 60 may not include the third barrier metal layer 64 and the third adhesion layer 65.

First to fifth embodiments may be combined as appropriate.

### Substrate

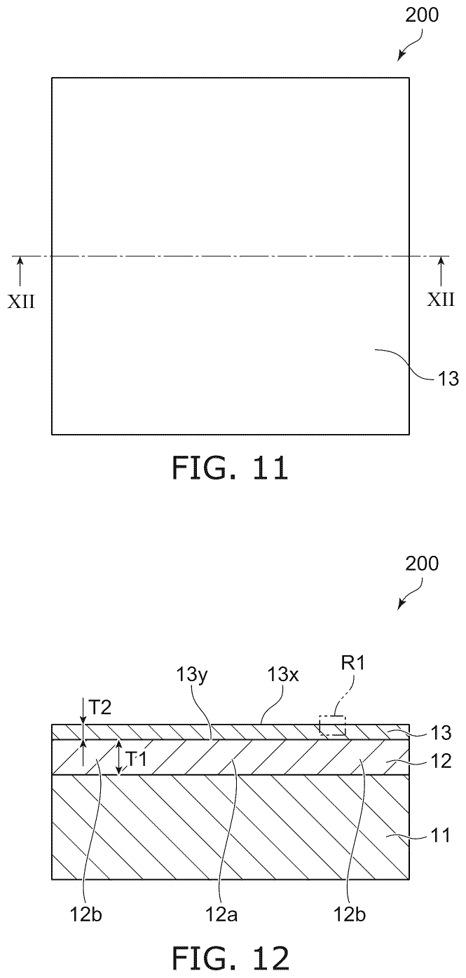

FIG. 11 is a plan view illustrating a substrate according to an embodiment.

FIG. 12 is a cross-sectional view illustrating the substrate according to the embodiment.

FIG. 12 is a cross-sectional view at the position of line XII-XII shown in FIG. 11.

As illustrated in FIGS. 11 and 12, the substrate 200 according to the embodiment includes the first base part 11, the first barrier metal layer 12, and the first adhesion layer 13. The substrate 200 is used to manufacture the semiconductor device 100 described above.

The first base part 11 and the first barrier metal layer 12 are similar to the lead frame 10 and the first barrier metal layer 12 of the semiconductor device 100 described above, and a description is therefore omitted. The first barrier metal layer 12 is located on at least one surface of the first base part 11. The first barrier metal layer 12 is located on at least a surface of the first base part 11 at the side at which the semiconductor element 30 is mounted.

In the substrate 200, the first adhesion layer 13 is located on the first barrier metal layer 12. The first adhesion layer 13 is located at least on the first barrier metal layer 12 located at the surface of the first base part 11 at the side at which the semiconductor element 30 is mounted. The first adhesion layer 13 covers at least a portion of the first barrier metal layer 12. It is favorable for the first adhesion layer 13 to cover the entire surface of the first barrier metal layer 12. In the substrate 200, the first adhesion layer 13 is located not only on the first sealing region 12b of the first barrier metal layer 12 but also on the first solder region 12a. In the substrate 200, the first adhesion layer 13 is provided over the entire surface of the first barrier metal layer 12. Otherwise, the first adhesion layer 13 of the substrate 200 is similar to the first adhesion layer 13 of the semiconductor device 100 described above, and a description is therefore omitted.

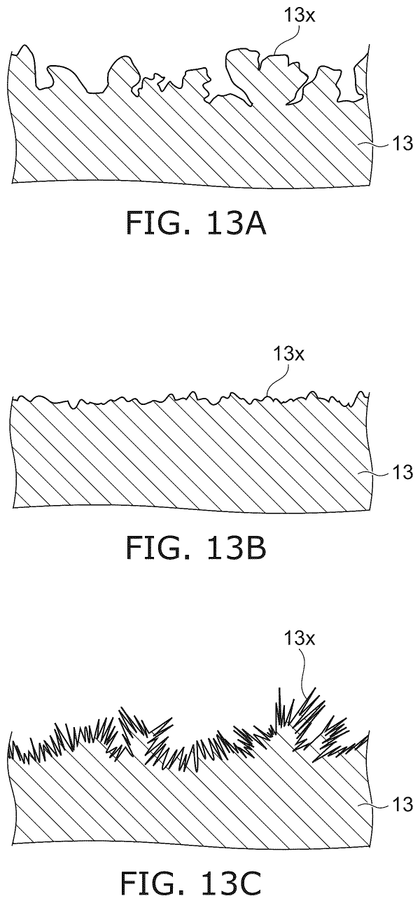

FIGS. 13A to 13C are cross-sectional views illustrating portions of substrates according to the embodiment.

FIGS. 13A to 13C are enlarged views of region R1 shown in FIG. 12.

As illustrated in FIGS. 13A to 13C, the upper surface 13x of the first adhesion layer 13 is, for example, roughened.

FIG. 13A illustrates the upper surface 13x of the first adhesion layer 13 that is roughened by roughening plating. As illustrated in FIG. 13A, the upper surface 13x of the first adhesion layer 13 that is roughened by roughening plating has, for example, a large unevenness having a depth of not less than 1 μm and not more than 2 μm. The average surface roughness of the upper surface 13x of the first adhesion layer 13 roughened by roughening plating is, for example, 1.8 μm.

FIG. 13B illustrates the upper surface 13x of the first adhesion layer 13 that is roughened by etching processing. As illustrated in FIG. 13B, the upper surface 13x of the first adhesion layer 13 that is roughened by etching processing has, for example, a small unevenness having a depth of less than 1 μm. The average surface roughness of the upper surface 13x of the first adhesion layer 13 roughened by etching processing is, for example, 0.6 μm.

FIG. 13C illustrates the upper surface 13x of the first adhesion layer 13 that is roughened by blackening. As illustrated in FIG. 13C, the upper surface 13x of the first adhesion layer 13 that is roughened by blackening has a needle-like unevenness. The average surface roughness of the upper surface 13x of the first adhesion layer 13 roughened by blackening is, for example, 1.5 μm.

### Method for Manufacturing Semiconductor Device

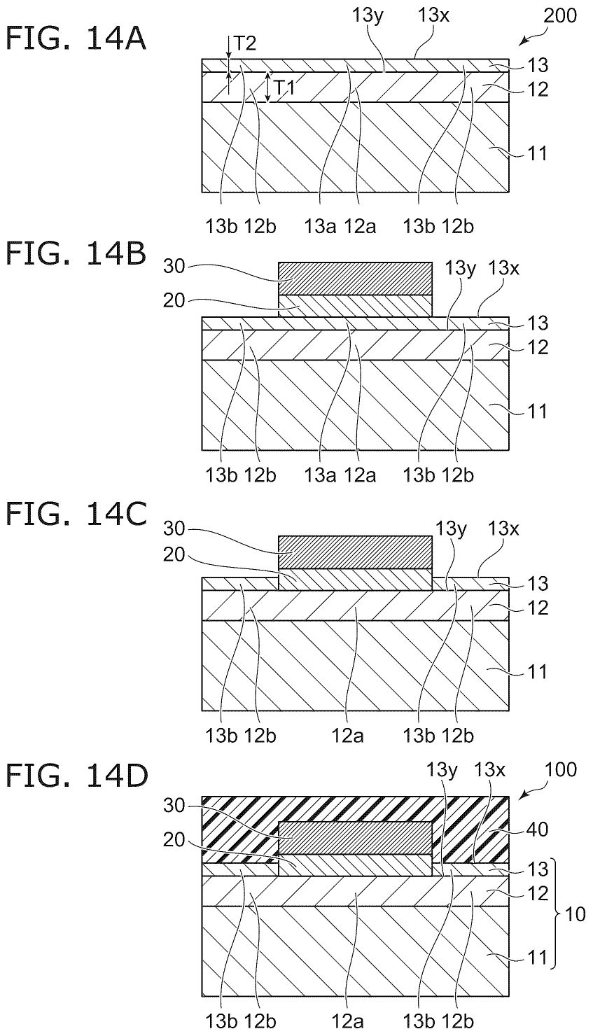

FIGS. 14A to 14D are cross-sectional views illustrating a method for manufacturing the semiconductor device according to the embodiment.

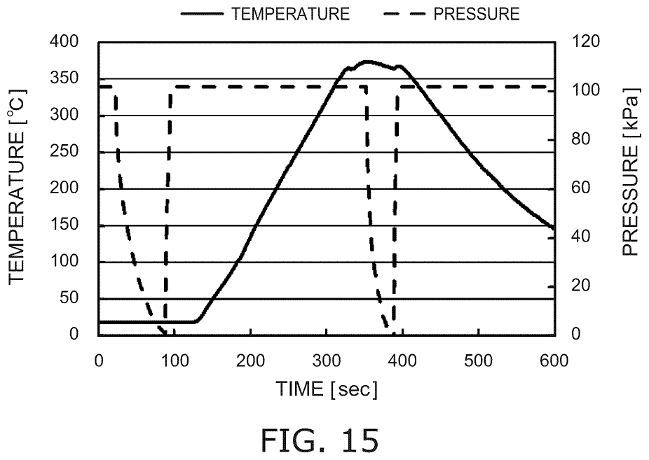

FIG. 15 is a graph illustrating an example of a reflow profile of the method for manufacturing the semiconductor device according to the embodiment.

As illustrated in FIGS. 14A to 14D, the method for manufacturing the semiconductor device according to the embodiment includes a first process, a second process, a third process, and a fourth process.

In the first process, the substrate 200 that includes the first base part 11, the first barrier metal layer 12, and the first adhesion layer 13 is prepared. The substrate 200 is similar to the substrate 200 described above, and a description is therefore omitted. The first barrier metal layer 12 includes the first solder region 12a and the first sealing region 12b. The first adhesion layer 13 includes a first adhesion region 13a and a second adhesion region 13b. The first adhesion region 13a is positioned on the first solder region 12a. The second adhesion region 13b is positioned on the first sealing region 12b. For example, the formation of the first barrier metal layer 12 and the first adhesion layer 13 is performed by plating, physical vapor deposition, chemical vapor deposition, etc. It is favorable for the formation of the first barrier metal layer 12 and the first adhesion layer 13 to be performed by plating. The first barrier metal layer 12 covers a portion or the entire surface of the first base part 11. The first adhesion layer 13 is located at the surface of the first barrier metal layer 12 at the side opposite to the first base part 11. The first adhesion layer 13 covers a portion or the entire surface of the first barrier metal layer 12.

When the upper surface 13x of the first adhesion layer 13 is roughened, the processing for roughening the upper surface 13x of the first adhesion layer 13 is performed in the first process. The processing for roughening may be performed for only a portion of the upper surface 13x of the first adhesion layer 13, or may be performed for the entire surface of the upper surface 13x of the first adhesion layer 13. The processing for roughening is performed on at least the upper surface of the second adhesion region 13b. The processing for roughening may be performed for the upper surface of the first adhesion region 13a and the upper surface of the second adhesion region 13b.

For example, the roughening of the upper surface 13x of the first adhesion layer 13 is performed by roughening plating, etching processing, or blackening. For example, the roughening plating forms a plating layer having a granular uneven shape in the surface in the plating processing process for forming the first adhesion layer 13. For example, an uneven shape is formed by the etching processing and the blackening by the upper surface 13x of the first adhesion layer 13 being partially dissolved by chemical processing with an acidic chemical liquid after forming the first adhesion layer 13.

In the second process, the semiconductor element 30 is located on the first adhesion region 13a of the first adhesion layer 13 of the substrate 200 with the first solder layer 20 interposed. The first solder layer 20 is located at the surface of the first adhesion layer 13 at the side opposite to the first base part 11. More specifically, the second process includes coating cream solder paste used as the material of the first solder layer 20 on the first adhesion region 13a of the first adhesion layer 13, and placing the semiconductor element 30 on the solder paste. Instead of coating cream solder paste on the first adhesion layer 13, a solder sheet and/or a solder wire may be placed on the first adhesion region 13a of the first adhesion layer 13.

The third process includes performing reflow of the first solder layer 20 to diffuse the portion of the first adhesion layer 13 (the first adhesion region 13a) contacting the first solder layer 20 into the first solder layer 20 to cause the first solder layer 20 to contact the first barrier metal layer 12 (the first solder region 12a). As a result, the first adhesion region 13a of the first adhesion layer 13 is removed, and the second adhesion region 13b of the first adhesion layer 13 remains. The first barrier metal layer 12 includes a metal having a diffusion rate into solder that is less than that of copper. Therefore, when performing reflow of the first solder layer 20, the first adhesion layer 13 that includes copper dissolves in the first solder layer 20, whereas the first barrier metal layer 12 remains without dissolving in the first solder layer 20.

As illustrated in FIG. 15, the reflow of the first solder layer 20 is performed by changing the temperature and the pressure. The vertical axis of FIG. 15 is the temperature and the pressure; and the horizontal axis of FIG. 15 is time. In FIG. 15, the temperature is illustrated by a solid line; and the pressure is illustrated by a broken line. For example, the reflow is performed using the following conditions.
Temperature raising rate from 150 to 350° C.: 1.8° C./sec
Holding time at 350° C. and higher: 98 seconds
Peak temperature: 374° C.

The reflow conditions described above are an example when tin-antimony solder (product name: H3637 made by Senju Metal Industry Co., Ltd.) having a solidus temperature of not less than 320° C. and a liquidus temperature of not less than 350° C. is used as the solder material, but the reflow conditions are not limited thereto.

The average void fraction of the first solder layer 20 can be reduced by the voids inside the first solder layer 20 being discharged outside the first solder layer 20 by decompression processing in which the pressure inside the heating furnace is reduced at the timing of the solder melting in the reflow. The pressure inside the heating furnace in the decompression processing is, for example, not more than 1,000 Pa, favorably not more than 10 Pa, and more favorably not more than 1 Pa. By setting the thickness of the first solder layer 20 to be, for example, not less than 20 μm, and favorably not less than 40 μm, the voids move easily during the decompression processing; and the average void fraction of the first solder layer 20 can be reduced. By setting the thickness of the first adhesion layer 13 to be, for example, not more than 2 μm, favorably not more than 1 μm, and more favorably not more than 0.5 μm, degradation of the fluidity of the solder when Cu (the first adhesion layer 13) dissolves in the molten solder (the first solder layer 20), which would make it difficult for the voids to be discharged, can be suppressed, and so the average void fraction of the first solder layer 20 can be reduced. For example, these techniques can be used to set the average void fraction of the first solder layer 20 to be less than 2.5%.

The fourth process includes disposing the sealing resin layer 40 on the semiconductor element 30 and on the first adhesion layer 13 (the second adhesion region 13b). To form the sealing resin layer 40, for example, an epoxy resin, which is a thermosetting resin, is used with the following conditions.
Molding temperature: 185° C.
Cure time: 60 seconds
Holding pressure: 12 MPa
After cure: 175° C. for 4 hours

The semiconductor device 100 according to the embodiment can be manufactured by the first to fourth processes described above. According to the method for manufacturing the semiconductor device according to the embodiment, the semiconductor device can be manufactured by realizing both the high-temperature reliability of the solder bonding portion and the adhesion between the lead frame 10 and the sealing resin layer 40. Descriptions of wire bonding and lead (connector) bonding are omitted from the method for manufacturing the semiconductor device described above.

According to the method for manufacturing the semiconductor device according to the embodiment, one semiconductor device 100 may be manufactured from one substrate 200, or multiple semiconductor devices 100 may be manufactured from one substrate 200. For example, the manufacturing cost can be reduced by manufacturing multiple semiconductor devices 100 from one substrate 200. In the following description, multiple semiconductor devices 100 are manufactured from one substrate 200.

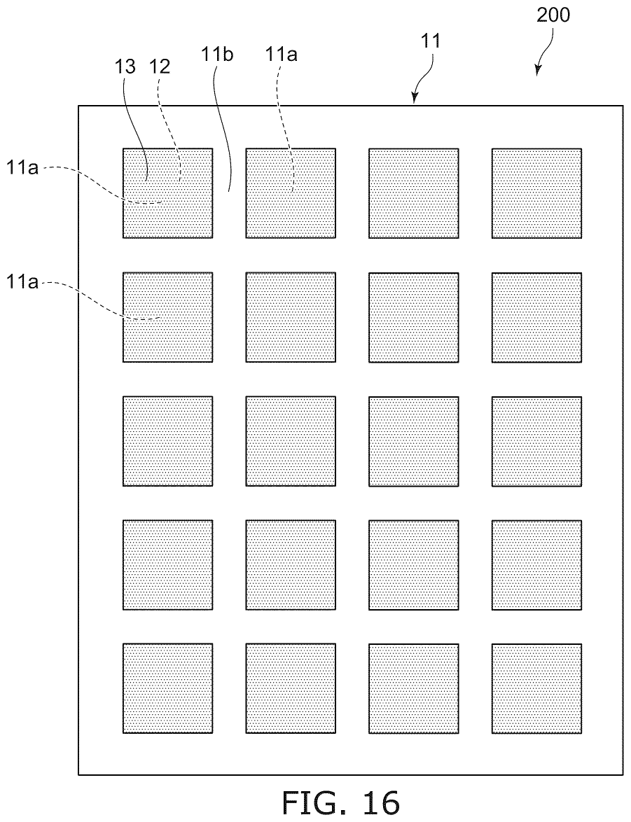

FIG. 16 is a plan view illustrating the method for manufacturing the semiconductor device according to the embodiment.

As illustrated in FIG. 16, when multiple semiconductor devices 100 are manufactured from one substrate 200, the first process includes preparing the substrate 200 on which the multiple semiconductor elements 30 can be placed. For example, the example of FIG. 16 shows a substrate 200 on which twenty semiconductor elements 30 can be placed.

In the example of FIG. 16, the first base part 11 includes a first portion 11a and a second portion 11b. The first portion 11a is a portion on which the semiconductor element 30 is placed. The second portion 11b is a portion on which the semiconductor element 30 is not placed. The first barrier metal layer 12 and the first adhesion layer 13 are located on the first portion 11a. The first barrier metal layer 12 and the first adhesion layer 13 are not located on the second portion 11b.

As illustrated in FIG. 16, the first base part 11 includes, for example, multiple first portions 11a that are separated from each other, and the second portion 11b positioned between the multiple first portions 11a. For example, the first barrier metal layer 12 and the first adhesion layer 13 can be formed on the first portion 11a without forming the first barrier metal layer 12 and the first adhesion layer 13 on the second portion 11b by performing plating, physical vapor deposition, chemical vapor deposition, etc., in a state in which the second portion 11b is masked.

Thus, by not forming the first barrier metal layer 12 and the first adhesion layer 13 on the second portion 11b on which the semiconductor elements 30 are not placed, the manufacturing cost can be less than when the first barrier metal layer 12 and the first adhesion layer 13 are formed on both the first and second portions 11a and 11b (the entire surface of the first base part 11).

In the first process, by removing a prescribed portion of the first portion 11a by stamping after the first barrier metal layer 12 and the first adhesion layer 13 are formed on the first portion 11a, a placement portion on which the semiconductor element 30 is placed may be formed, and a wiring portion may be formed around the placement portion.

When manufacturing multiple semiconductor devices 100 from one substrate 200, for example, the second process, the third process, and the fourth process described above are performed after the first process, and then a fifth process of singulating the semiconductor devices 100 is performed. For example, the fifth process may be performed between the first process and the second process, may be performed between the second process and the third process, and may be performed between the third process and the fourth process.

### Examples/Comparative Examples

Examples and comparative examples will now be described.

### Examples 1-1 to 1-3 and Comparative Examples 1-1 to 1-2

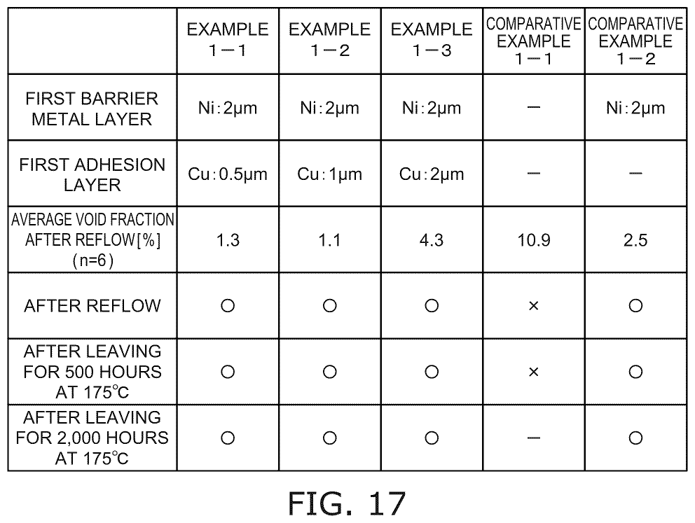

FIG. 17 is a table illustrating results of examples and comparative examples.

The average void fraction after reflow and the high-temperature reliability of the solder bonding portion were evaluated for the examples 1-1 to 1-3, in which samples of semiconductor devices were manufactured using substrates in which the first barrier metal layer made of nickel was located on the first base part made of copper, and the first adhesion layer made of copper was located on the first barrier metal layer. The average void fraction after reflow and the high-temperature reliability of the solder bonding portion were evaluated for the comparative example 1-1, in which a sample of a semiconductor device was manufactured using a substrate in which the first barrier metal layer and the first adhesion layer were not provided on the first base part made of copper. The average void fraction after reflow and the high-temperature reliability of the solder bonding portion were evaluated for the comparative example 1-2, in which samples of semiconductor devices were manufactured using substrates in which the first barrier metal layer made of nickel was located on the first base part made of copper, and the first adhesion layer was not located on the first barrier metal layer. The thicknesses of the layers were as shown in FIG. 17. High-temperature lead-free solder “H3637” made by Senju Metal Industry Co., Ltd. was used as the solder material for the examples 1-1 to 1-3 and the comparative examples 1-1 to 1-2. The results are shown in FIG. 17. The average void fraction was calculated as the average value of the void fractions of the solder layers of six samples. The high-temperature reliability of the solder bonding portion is marked with “o” for solder bonding portions having no large voids or detachment, and marked with “x” for solder bonding portions having large voids or detachment.

The void fraction of the solder layer was acquired using the following procedure. First, an X-ray inspection apparatus TUX-3210N made by Mars Tohken Solution Co. Ltd. was used to image a see-through X-ray image of the solder layer. The Imaging conditions of the see-through X-ray image were set to a tube voltage of 80 kV, a tube current of 100 μA, a focal size of 3, and a Z-axis coordinate of 50 mm. Then, the void fraction was calculated by measuring the void area based on the X-ray image, and by defining the void fraction to be the ratio of the void area to the area of the entire bonding surface. To calculate the void fraction, the bump analysis software BAG made by Mars Tohken Solution Co. Ltd. was used, the X-ray image that was imaged was read into image software, then highlighting and shadow conditions were set in the “image acquisition settings”, and the contrast of the image was adjusted. After setting the inspection area using the X-ray image, the void inspection technique in “inspection settings” was set to “void inspection inside designated area”, smoothing (with the filter size set to 10) was performed, “for void detection” was set, and the threshold was determined so that the void shape and size matched between the binarized image and the X-ray image that was imaged. The void fraction also can be calculated with generic image processing software.

As illustrated in FIG. 17, for the comparative example 1-1 in which the first barrier metal layer and the first adhesion layer were not included, the average void fraction after reflow was high, and large voids had occurred after reflow. Also, solder detachment had occurred after leaving for 500 hours at 175° C. In contrast, for the examples 1-1 to 1-3 and the comparative example 1-2 that included the first barrier metal layer, compared to the comparative example 1-1, the average void fraction after reflow was low, and there were neither large voids nor detachment after leaving for 500 hours at 175° C. and after leaving for 2,000 hours at 175° C. after reflow. This suggests that the high-temperature reliability of the solder bonding portion can be increased by providing the first barrier metal layer.

### Examples 2-1 to 2-6 and Comparative Examples 2-1 to 2-2

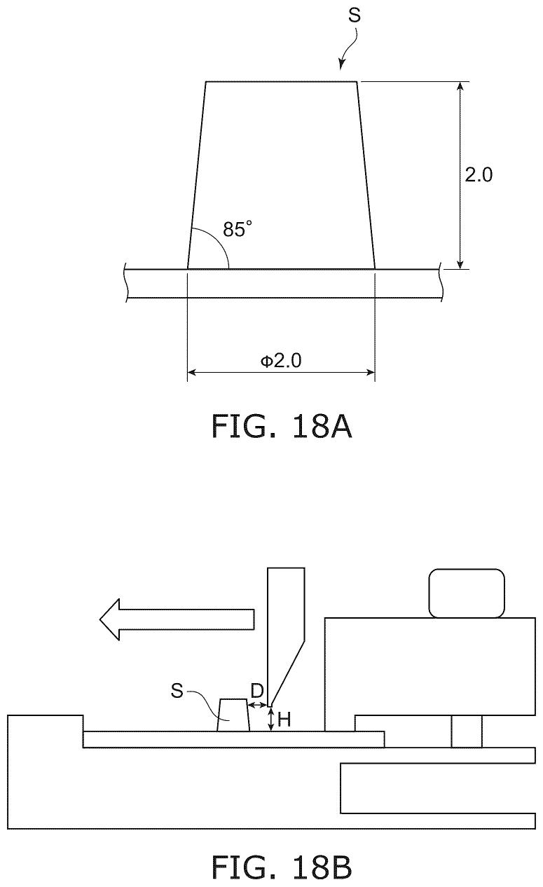

FIGS. 18A and 18B are explanatory drawings illustrating a method for measuring the adhesion strength of the examples and the comparative examples.

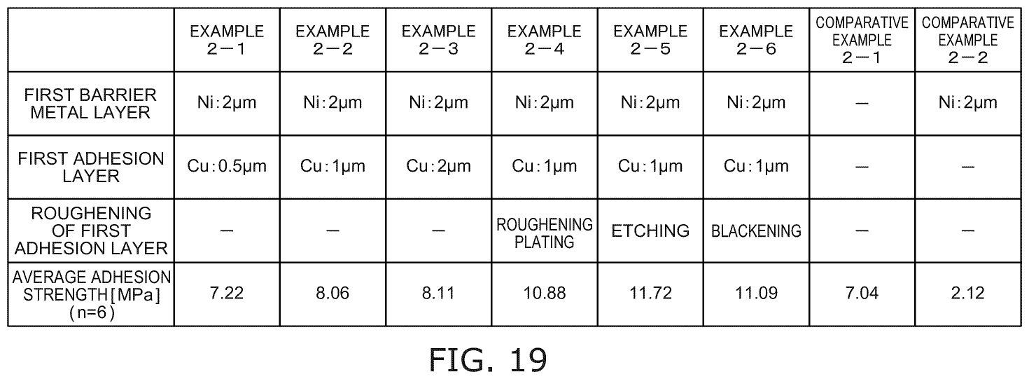

FIG. 19 is a table illustrating results of the examples and the comparative examples.

The adhesion between the substrate and the sealing resin was evaluated for the examples 2-1 to 2-6 in which samples of semiconductor devices manufactured using substrates in which the first barrier metal layer made of nickel was located on the first base part made of copper, and the first adhesion layer made of copper was located on the first barrier metal layer. Roughening of the upper surface of the first adhesion layer was not performed for the examples 2-1 to 2-3. Roughening of the upper surface of the first adhesion layer was performed for the examples 2-4 to 2-6 by using the method according to FIG. 19. The adhesion between the substrate and the sealing resin was evaluated for the comparative example 2-1 in which a sample of a semiconductor device manufactured using substrates in which the first barrier metal layer and the first adhesion layer were not provided on the first base part made of copper. The adhesion between the substrate and the sealing resin was evaluated for the comparative example 2-2 in which a sample of a semiconductor device manufactured using a substrate in which the first barrier metal layer made of nickel was located on the first base part made of copper, and the first adhesion layer was not provided on the first barrier metal layer. The thicknesses of the layers were as described in FIG. 19. The epoxy resin “EME-G501B” made by Sumitomo Bakelite Co., Ltd. was used as the sealing resin for the examples 2-1 to 2-6 and the comparative examples 2-1 to 2-2. The results are shown in FIG. 19. The average adhesion strength was calculated as the average value of six samples.

The adhesion between the substrate and the sealing resin was evaluated as follows. First, as illustrated in FIG. 18A, a sample S in which the sealing resin was formed was prepared to have a diameter of 2.0 mm, a height of 2.0 mm, and an angle of 85 degrees. Then, as illustrated in FIG. 18B, the sample S was fixed to a measuring apparatus; and the measurement was performed. The sample S was fixed at a position having a distance D of not less than 300 μm and having no resin burr. The measurement conditions were as follows.
Load cell: 5 kg
Tool: Nordson DAGE SHR-187-5000
Shear rate: 100 μm/s
Shear height (H): 1,500 μm
Tool movement amount: 500 μm
Maximum distance: 2,000 μm

As illustrated in FIG. 19, the average adhesion strength was low for the comparative example 2-2 in which the first adhesion layer was not provided. In contrast, compared to the comparative example 2-2, the average adhesion strength was high for the examples 2-1 to 2-6 in which the first adhesion layer was provided. This suggests that the adhesion between the lead frame and the sealing resin can be improved by providing the first adhesion layer on the first barrier metal layer. Compared to the examples 2-1 to 2-3 in which the upper surface of the first adhesion layer was not roughened, the average adhesion strength was high for the examples 2-4 to 2-6 in which the upper surface of the first adhesion layer was roughened. This suggests that the adhesion between the lead frame and the sealing resin can be further improved by roughening the upper surface of the first adhesion layer.

### Examples 3-1 to 3-6 and Comparative Examples 3-1 to 3-2

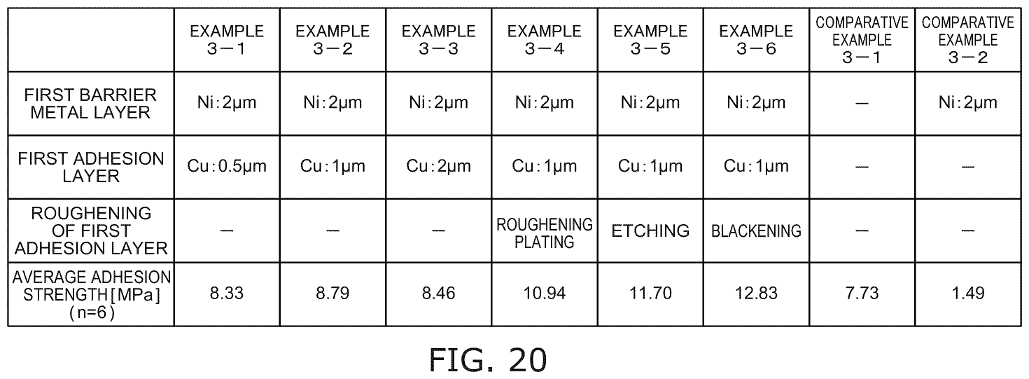

FIG. 20 is a table illustrating results of the examples and the comparative examples.

Other than the epoxy resin “EME-G700LTD” made by Sumitomo Bakelite Co., Ltd. being used as the sealing resin, the examples 3-1 to 3-6 and the comparative examples 3-1 to 3-2 were similar to the examples 2-1 to 2-6 and the comparative examples 2-1 to 2-2; and the adhesion between the substrate and the sealing resin was evaluated. The thicknesses of the layers were as described in FIG. 20. The results are shown in FIG. 20. The average adhesion strength was calculated as the average value of six samples.

As illustrated in FIG. 20, the average adhesion strength was low for the comparative example 3-2 in which the first adhesion layer was not provided. In contrast, compared to the comparative example 3-2, the average adhesion strength was high for the examples 3-1 to 3-6 in which the first adhesion layer was provided. This suggests that the adhesion between the lead frame and the sealing resin can be improved by providing the first adhesion layer on the first barrier metal layer. Also, compared to the examples 3-1 to 3-3 in which the upper surface of the first adhesion layer was not roughened, the average adhesion strength was high for the examples 3-4 to 3-6 in which the upper surface of the first adhesion layer was roughened. This suggests that the adhesion between the lead frame and the sealing resin can be further improved by roughening the upper surface of the first adhesion layer.

It is therefore suggested that both the high-temperature reliability of the solder bonding portion and the adhesion between the lead frame and the sealing resin can be realized by providing the first barrier metal layer on the first base part and by providing the first adhesion layer on the first barrier metal layer.

Embodiments may include the following configurations.

### Configuration 1

A semiconductor device, comprising:
a lead frame;
a first solder layer located on the lead frame;
a semiconductor element located on the first solder layer; and
a sealing resin layer located on the semiconductor element and on the lead frame,
the lead frame including
   a first base part,
   a first barrier metal layer located on the first base part, the first barrier metal layer including a first solder region and a first sealing region, the first barrier metal layer including a metal with a diffusion rate into solder less than that of copper, and
   a first adhesion layer located on the first sealing region, the first adhesion layer including copper,
the first solder layer being located on the first solder region,
the sealing resin layer being located on the semiconductor element and on the first adhesion layer.

### Configuration 2

The semiconductor device according to Configuration 1, wherein
a thickness of the first barrier metal layer is not less than 0.05 μm and not more than 5 μm.

### Configuration 3

The semiconductor device according to Configuration 1 or 2, wherein
the first barrier metal layer includes at least one selected from the group consisting of nickel, chrome, and titanium.

### Configuration 4

The semiconductor device according to any one of Configurations 1 to 3, wherein
a thickness of the first adhesion layer is not less than 0.05 μm and not more than 2 μm.

### Configuration 5

The semiconductor device according to any one of Configurations 1 to 4, wherein
an upper surface of the first adhesion layer is roughened.

### Configuration 6

The semiconductor device according to any one of Configurations 1 to 5, wherein
the first solder layer includes at least one selected from the group consisting of tin, silver, copper, antimony, nickel, bismuth, and lead.

### Configuration 7

The semiconductor device according to any one of Configurations 1 to 6, wherein
an average void fraction of the first solder layer is less than 2.5%.

### Configuration 8

The semiconductor device according to any one of Configurations 1 to 7, further comprising:
a second solder layer located on the semiconductor element; and
a connector located on the second solder layer,
the connector including
   a second base part,
   a second barrier metal layer located under the second base part, the second barrier metal layer including a second solder region and a second sealing region, the second barrier metal layer including a metal with a diffusion rate into solder less than that of copper, and
   a second adhesion layer located under the second sealing region, the second adhesion layer including copper,
the second solder layer being located under the second solder region,
the sealing resin layer being located under the second adhesion layer.

### Configuration 9

The semiconductor device according to Configuration 8, further comprising:
a connection frame; and
a third solder layer located between the connection frame and the connector,
the connector further including
   a third barrier metal layer located under the second base part, the third barrier metal layer including a third solder region and a third sealing region, the third barrier metal layer including a metal with a diffusion rate into solder less than that of copper, and
   a third adhesion layer located under the third sealing region, the third adhesion layer including copper,
the third solder layer being located under the third solder region,
the sealing resin layer being located under the third adhesion layer.

### Configuration 10

The semiconductor device according to Configuration 8 or 9, further comprising:
a connection frame; and
a third solder layer located between the lead frame and the connector,
the connection frame further including
   a third base part,
   a fourth barrier metal layer located on the third base part, the fourth barrier metal layer including a fourth solder region and a fourth sealing region, the fourth barrier metal layer including a metal with a diffusion rate into solder less than that of copper, and
   a fourth adhesion layer located on the fourth sealing region, the fourth adhesion layer including copper,
the third solder layer being located on the fourth solder region,
the sealing resin layer being located on the fourth adhesion layer.

### Configuration 11

A method for manufacturing a semiconductor device, the method comprising:
a first process of preparing a substrate, the substrate including
   a first base part,
   a first barrier metal layer located on the first base part, the first barrier metal layer including a metal with a diffusion rate into solder less than that of copper, and
   a first adhesion layer located on an entire surface of the first barrier metal layer, the first adhesion layer including copper;
a second process of disposing a semiconductor element on the first adhesion layer with a first solder layer interposed;
a third process of causing the first solder layer to contact the first barrier metal layer by performing reflow of the first solder layer to diffuse, into the first solder layer, a portion of the first adhesion layer contacting the first solder layer; and
a fourth process of disposing a sealing resin layer on the semiconductor element and on the first adhesion layer.

### Configuration 12

The method for manufacturing the semiconductor device according to Configuration 11, wherein
a thickness of the first barrier metal layer is not less than 0.05 μm and not more than 5 μm.

### Configuration 13

The method for manufacturing the semiconductor device according to Configuration 11 or 12, wherein
the first barrier metal layer includes at least one selected from the group consisting of nickel, chrome, and titanium.

### Configuration 14

The method for manufacturing the semiconductor device according to any one of Configurations 11 to 13, wherein
a thickness of the first adhesion layer is not less than 0.05 μm and not more than 2 μm.

### Configuration 15

The method for manufacturing the semiconductor device according to any one of Configurations 11 to 14, wherein
the first process includes roughening an upper surface of the first adhesion layer.

### Configuration 16

The method for manufacturing the semiconductor device according to any one of Configurations 11 to 15, wherein
the first solder layer includes at least one selected from the group consisting of tin, silver, copper, antimony, nickel, bismuth, and lead.

### Configuration 17

A substrate, comprising:
a first base part;
a first barrier metal layer located on the first base part, the first barrier metal layer including a metal with a diffusion rate into solder less than that of copper; and
a first adhesion layer located on an entire surface of the first barrier metal layer, the first adhesion layer including copper.

### Configuration 18

The substrate according to Configuration 17, wherein
a thickness of the first barrier metal layer is not less than 0.05 μm and not more than 5 μm.

### Configuration 19

The substrate according to Configuration 17 or 18, wherein
the first barrier metal layer includes at least one selected from the group consisting of nickel, chrome, and titanium.

### Configuration 20

The substrate according to any one of Configurations 17 to 19, wherein
a thickness of the first adhesion layer is not less than 0.05 μm and not more than 2 μm.

### Configuration 21

The substrate according to Configuration 20, wherein
a thickness of the first adhesion layer is not more than 1.5 μm.

### Configuration 22

The substrate according to any one of Configurations 17 to 21, wherein
an upper surface of the first adhesion layer is roughened.

Thus, according to embodiments, a semiconductor device, a method for manufacturing a semiconductor device, and a substrate are provided in which both high-temperature reliability of a solder bonding portion and adhesion between a lead frame and a sealing resin can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments herein may be made without departing from the spirit of the inventions. The accompanying claims and their equivalents are intended to cover such forms or modifications as would fall within the scope and spirit of the inventions.

What is claimed is:

1. A semiconductor device, comprising:
a lead frame;
a first solder layer located on the lead frame;
a semiconductor element located on the first solder layer; and
a sealing resin layer located on the semiconductor element and on the lead frame,
the lead frame including
a first base part,
a first barrier metal layer located on the first base part, the first barrier metal layer including a first solder region and a first sealing region, the first barrier metal layer including a metal with a diffusion rate into solder less than that of copper, and
a first adhesion layer located on the first sealing region, the first adhesion layer including copper,
the first solder layer being located on the first solder region,
the sealing resin layer being located on the semiconductor element and on the first adhesion layer.

2. The semiconductor device according to claim 1, wherein
a thickness of the first adhesion layer is not less than 0.05 μm and not more than 2 μm.

3. The semiconductor device according to claim 1, wherein
an upper surface of the first adhesion layer is roughened.

4. The semiconductor device according to claim 1, wherein
an average void fraction of the first solder layer is less than 2.5%.

5. The semiconductor device according to claim 1, further comprising:
a second solder layer located on the semiconductor element; and
a connector located on the second solder layer,
the connector including
a second base part,
a second barrier metal layer located under the second base part, the second barrier metal layer including a second solder region and a second sealing region, the second barrier metal layer including a metal with a diffusion rate into solder less than that of copper, and
a second adhesion layer located under the second sealing region, the second adhesion layer including copper,
the second solder layer being located under the second solder region,
the sealing resin layer being located under the second adhesion layer.

6. A method for manufacturing a semiconductor device, the method comprising:
a first process of preparing a substrate, the substrate including
a first base part,
a first barrier metal layer located on the first base part, the first barrier metal layer including a metal with a diffusion rate into solder less than that of copper, and
a first adhesion layer located on an entire surface of the first barrier metal layer, the first adhesion layer including copper;
a second process of disposing a semiconductor element on the first adhesion layer with a first solder layer interposed;
a third process of causing the first solder layer to contact the first barrier metal layer by performing reflow of the first solder layer to diffuse, into the first solder layer, a portion of the first adhesion layer contacting the first solder layer; and
a fourth process of disposing a sealing resin layer on the semiconductor element and on the first adhesion layer.

7. The method for manufacturing the semiconductor device according to claim 6, wherein
the first barrier metal layer includes at least one selected from the group consisting of nickel, chrome, and titanium.

8. The method for manufacturing the semiconductor device according to claim 6, wherein
a thickness of the first adhesion layer is not less than 0.05 μm and not more than 2 μm.

9. The method for manufacturing the semiconductor device according to claim 6, wherein
the first process includes roughening an upper surface of the first adhesion layer.

10. A substrate, comprising:
a first base part;
a first barrier metal layer located on the first base part, the first barrier metal layer including a metal with a diffusion rate into solder less than that of copper; and
a first adhesion layer located on an entire surface of the first barrier metal layer, the first adhesion layer including copper.

11. The substrate according to claim 10, wherein
a thickness of the first adhesion layer is not less than 0.05 μm and not more than 2 μm.
